(19) United States
(12) Patent Application Publication
(10) Pub. No.: US 2012/0132534 A1
(43) Pub. Date: May 31, 2012

(54) Growth of nanotubes from patterned and ordered nanoparticles

(75) Inventor: Biswajit Das, Henderson, NV (US)

(73) Assignee: The Board of Regents of the Nev. Sys. Of Higher Ed on behalf of the UNLV

(21) Appl. No.: 11/983,324

(22) Filed: Nov. 8, 2007

Related U.S. Application Data
(63) Continuation-in-part of application No. 11/888,476, filed on Aug. 1, 2007, now Pat. No. 8,084,101.
(60) Provisional application No. 60/857,616, filed on Nov. 8, 2006.
(60) Provisional application No. 60/834,765, filed on Aug. 1, 2006.

(51) Int. Cl. C25D 11/02; B01J 8/08; B82Y 40/00

(52) U.S. Cl. 205/333; 427/595; 118/640; 977/842

(57) ABSTRACT

Methods, apparatus and systems form structures from nanoparticles by providing a source of nanoparticles, the particles being capable of being moved by application of a field, such as an electrical field, magnetic field and even electromagnetic radiation or fields such as light, UV, IR, radiowaves, radiation and the like; depositing the nanoparticles to a surface in a first distribution of the nanoparticles; applying a field to the nanoparticles on the surface that applies a force to the particles; and rearranging the nanoparticles on the surface by the force from the field to form a second distribution of nanoparticles on the surface. Nanoparticle catalysts can be deposited on the surfaces. The second distribution of nanoparticles is more ordered or more patterned than the first distribution of nanoparticles as a result of the rearranging. Nanotubes can then be grown on the ordered nanoparticle deposited catalysts.

### RELATED APPLICATIONS DATA

This Application claims priority from U.S. Provisional Patent Application 60/857,616, filed Nov. 8, 2006, and also is a Continuation-in-Part Application of U.S. patent application Ser. No. 11/888,476, filed Aug. 1, 2007, and titled FABRICATION OF PATTERENED AND ORDERED NANOPARTICLES, which in turn claims priority from U.S. Provisional Patent Application 60/834,765 filed Aug. 1, 2006.

### BACKGROUND OF THE INVENTION

1. Field of the invention

The present invention relates to the field of nanoparticles and nanotechnology, fabrication of nanotechnology, fabrication of patterned and ordered nanotechnology and devices, and fabrication of nanotubes from the ordered nanoparticles. The invention also relates to the field of fabrication of electronic, electrical and photonic devices using nanotechnology.

2. Background of the Art

Nanotechnology is an anticipated manufacturing technology giving thorough, inexpensive control of the structure of matter through the manipulation of individual atoms. The term has been used to refer to any attempt to work at the submicron scale, but this site mainly covers the subset usually called molecular nanotechnology. Broadly speaking, the central thesis of nanotechnology is that almost any chemically stable structure can be built from a dimensional level that includes final structures having at least one dimension remaining in the realm of from about 0.2 to 50 nanometers. Other dimensions, such as lengths of tubes, many exceeded these ranges, but diameters and/or thicknesses may remain within that dimensional realm.

Presently, the vast majority of commercial manufacturing technologies manipulate millions and billions of atoms at a time using conventional shaping technologies. Atoms and molecules are shaped into products by pounding, molding, extruding, deposition, coating, chipping and other large scale mechanical deformation and accumulation technologies. For example, chips can be made by forming pure silicon substrates and then etching and depositing patterns of atoms and molecules on its surface. These techniques depend on large scale manipulation of atomic and molecular materials. The present commercial systems and techniques for the manipulation of molecules and atoms into small masses, such zs those associated with nanotechnology is still too high an order of complexity today for existing mass production techniques to be applied to nanotechnology. The quality of the control of the deposition of atomic materials requires the sacrifice of manufacturing speeds to assure quality replication of intended designs. In the future, molecular nanotechnology will require more sophisticated yet high speed control over the placement of individual atoms.

Often, nanotechnology is referred to as “bottom-up” manufacturing. Its aim is to start with the smallest possible building materials, atoms and molecules, and use them to create a desired product. Working with individual atoms and individual molecules allows the atom-by-atom or molecule by molecule design of structures.

An ultimate objective of nanotechnology is to get essentially every atom and molecule in the right place, make almost any type of material structure that is consistent with the laws of physics and chemistry, and to have manufacturing costs that do not greatly exceed the cost of the required raw materials and energy.

Wilson Ho, Hyojune Lee, “Single bond formation and characterization with a scanning tunneling microscope,” Science 286(26 Nov. 1999):1719-1722; http://www.physics.uci.edu/˜wilsonho/stm-iets.html describes the use of Atomic Force Microscopes for changing physical properties on surfaces in the aim of creating a surface structure that can be used to direct technology as extremely small regions on surfaces. This is one type of technology envisioned as attempting to get every atom in the right place. This is necessary to develop techniques, processes, protocols and machines, often termed assemblers, that can force site-specific chemical reactions or atomic/molecular placement or materials. To find structures consistent with the laws of chemistry and physics, molecular modeling software will be used.

Single-wall carbon nanotubes have been made in a DC arc discharge apparatus by simultaneously evaporating carbon and a small percentage of Group VIIIb transition metal from the anode of the arc discharge apparatus. These techniques allow production of only a low yield of carbon nanotubes, and the population of carbon nanotubes exhibits significant variations in structure and size.

Another method of producing single-wall carbon nanotubes involves laser vaporization of a graphite substrate doped with transition metal atoms (such as nickel, cobalt, or a mixture thereof) to produce single-wall carbon nanotubes. The single-wall carbon nanotubes produced by this method tend to be formed in clusters, termed “ropes,” of about 10 to about 1000 single-wall carbon nanotubes in parallel alignment, held by van der Waals forces in a closely packed triangular lattice. Nanotubes produced by this method vary in structure, although one structure tends to predominate. Although the laser vaporization process produces an improved yield of single-wall carbon nanotubes, the product is still heterogeneous, and the nanotubes tend to be too tangled for many potential uses of these materials. In addition, the laser vaporization of carbon is a high energy process.

Carbon nanotubes (also referred to as carbon fibrils) are seamless tubes of graphite sheets with full fullerene caps which were first discovered as multilayer concentric tubes or multi-walled carbon nanotubes and subsequently as single-walled carbon nanotubes in the presence of transition metal catalysts. Carbon nanotubes have shown promising applications including nanoscale electronic devices, high strength materials, electron field emission, tips for scanning probe microscopy, and gas storage.

Generally, single-walled carbon nanotubes are preferred over multi-walled carbon nanotubes for use in these applications because they have fewer defects and are therefore stronger and more conductive than multi-walled carbon nanotubes of similar diameter. Defects are less likely to occur in single-walled carbon nanotubes than in multi-walled carbon nanotubes because multi-walled carbon nanotubes can survive occasional defects by forming bridges between unsaturated carbon valances, while single-walled carbon nanotubes have no neighboring walls to compensate for defects.

However, the availability of these new single-walled carbon nanotubes in quantities necessary for practical technology is still problematic. Large scale processes for the production of high quality single-walled carbon nanotubes are still needed.

Presently, there are three main approaches for synthesis of carbon nanotubes. These include the laser ablation of carbon (Thess, A. et al., Science, 273:483, 1996), the electric arc discharge of graphite rod (Journet, C. et al., Nature, 388:756, 1997), and the chemical vapor deposition of hydrocarbons (Ivanov, V. et al., Chem. Phys. Lett, 223:329, 1994; Li A. et al., Science, 274:1701, 1996). The production of multi-walled carbon nanotubes by catalytic hydrocarbon cracking is now on a commercial scale (U.S. Pat. No. 5,578,543) while the production of single-walled carbon nanotubes is still in a gram scale by laser (Rinzler, A. G. et al., Appl. Phys. A., 67:29, 1998) and arc (Journet, C. et al., Nature, 388:756, 1997) techniques.

Unlike the laser and arc techniques, carbon vapor deposition over transition metal catalysts tends to create multi-walled carbon nanotubes as a main product instead of single-walled carbon nanotubes. However, there has been some success in producing single-walled carbon nanotubes from the catalytic hydrocarbon cracking process. Dai et al. (Dai, H. et al., Chem. Phys. Lett, 260:471 1996) demonstrate web-like single-walled carbon nanotubes resulting from disproportionation of carbon monoxide (CO) with a molybdenum (Mo) catalyst supported on alumina heated to 1200° From the reported electron microscope images, the Mo metal obviously attaches to nanotubes at their tips. The reported diameter of single-walled carbon nanotubes generally varies from 1 nm to 5 nm and seems to be controlled by the Mo particle size. Catalysts containing iron, cobalt or nickel have been used at temperatures between 850° to 1200° to form multi-walled carbon nanotubes (U.S. Pat. No. 4,663,230). Recently, rope-like bundles of single-walled carbon nanotubes were generated from the thermal cracking of benzene with iron catalyst and sulfur additive at temperatures between 1100-1200° (Cheng, H. M. et al., Appl. Phys. Lett., 72:3282, 1998; Cheng, H. M. et al., Chem. Phys. Lett., 289:602, 1998). The synthesized single-walled carbon nanotubes are roughly aligned in bundles and woven together similarly to those obtained from laser vaporization or electric arc method. The use of laser targets comprising one or more Group VI or Group VIII transition metals to form single-walled carbon nanotubes has been proposed (WO98/39250). The use of metal catalysts comprising iron and at least one element chosen from Group V (V, Nb and Ta), VI (Cr, Mo and W), VII (Mn, Tc and Re) or the lanthanides has also been proposed (U.S. Pat. No. 5,707,916). However, methods using these catalysts have not been shown to produce quantities of nanotubes having a high ratio of single-walled carbon nanotubes to multi-walled carbon nanotubes. Moreover, metal catalysts are an expensive component of the production process.

Another way to synthesize carbon nanotubes is by catalytic decomposition of a carbon-containing gas by nanometer-scale metal particles supported on a substrate. The carbon feedstock molecules decompose on the particle surface, and the resulting carbon atoms then precipitate as part of a nanotube from one side of the particle. This procedure typically produces imperfect multi-walled carbon nanotubes.

Another method for production of single-wall carbon nanotubes involves the disproportionation of CO to form single-wall carbon nanotubes and CO.sub.2 on alumina supported transition metal particles comprising Mo, Fe, Ni, Co, or mixtures thereof. This method uses inexpensive feedstocks in a moderate temperature process. However, the yield is limited due to rapid surrounding of the catalyst particles by a dense tangle of single-wall carbon nanotubes, which acts as a barrier to diffusion of the feedstock gas to the catalyst surface, limiting further nanotube growth.

Control of ferrocene/benzene partial pressures and addition of thiophene as a catalyst promoter in an all gas phase process can produce single-wall carbon nanotubes. However, this method suffers from simultaneous production of multi-wall carbon nanotubes, amorphous carbon, and other products of hydrocarbon pyrolysis under the high temperature conditions necessary to produce high quality single-wall carbon nanotubes.

More recently, a method for producing single-wall carbon nanotubes has been reported that uses high pressure CO as the carbon feedstock and a gaseous transition metal catalyst precursor as the catalyst. (“Gas Phase Nucleation and Growth of Single-Wall Carbon Nanotubes from High Pressure Carbon Monoxide,” International Pat. Publ. WO 00/26138, published May 11, 2000, incorporated by reference herein in its entirety). This method possesses many advantages over other earlier methods. For example, the method can be done continuously, and it has the potential for scale-up to produce commercial quantities of single-wall carbon nanotubes. Another significant advantage of this method is its effectiveness in making single-wall carbon nanotubes without simultaneously making multi-wall nanotubes. Furthermore, the method produces single-wall carbon nanotubes in high purity, such that less than about 10 wt % of the carbon in the solid product is attributable to other carbon-containing species, which includes both graphitic and amorphous carbon.

A major challenge facing nanotechnology today is the fabrication of electronic and photonic devices in a commercially viable manner. One prerequisite for such commercial applications lies in the ability to enable mass fabrication as well as the ability to create ‘ordering and patterning’ of a large number of nanoparticles in a cost effective manner. One methodology for forming patterned nanotubes is a photolithographic process, such as that described in U.S. Pat. No. 6,960,425 (Jung et al.). In the Jung et al. Patent, a method for forming a pattern of carbon nanotubes includes forming a pattern on a surface-treated substrate using a photolithographic process, and laminating carbon nanotubes thereon using a chemical self-assembly process so as to form the carbon nanotubes in a monolayer or multilayer structure. A monolayer or multilayer carbon nanotube pattern may be easily formed on the substrate, e.g., glass, a silicon wafer and a plastic. Accordingly, the method can be applied to form patterned carbon nanotube layers having a high conductivity, and thus will be usefully utilized in the manufacturing processes of energy storages, for example, solar cells and batteries, flat panel displays, transistors, chemical and biological sensors, semiconductor devices and the like. The technology thus forms the distribution of pattern seeds by photolithography, and then grows the seeds by other deposition methods.

Various methods, apparatus and materials for providing materials for growth of nanotubes are disclosed, for example, in US patents and Applications such as U.S. Pat. No. 7,052,668, which are incorporated herein by reference in their entirety for their disclosures, as are all other applications, patents and articles referenced herein.

Another proposed format of nanotechnology envisions self replicating assemblers that would work by using its ability to make site-specific chemical reactions to make copies of itself. These copies can then make copies of themselves also, and so on. Eventually, the assembler multitude can then work in parallel to build molecular structures. This has been referred to as genetic manufacturing since it assumes oriented duplication as occurs in biological operation of genetics. This massive parallelism would lead to great economies of scale, but it is still necessary to create the first self-replicating structure by an non-replication process and assembler. These assemblers can be compared to the molecular machinery evident in cells today.

Nanotechnology has not yet been developed on a commercial scale, but molecular models of possible nanomachines are becoming increasingly common. Often, these models analyze the basic tools necessary for a nanotechnological part that could go into tools such as an assembler. It is a fundamental need of the future of nanotechnology to find basic manufacturing processes and schemes that can be used to mass produce and accurately produce surfaces and materials that provide advances in nanotechnology and its systems.

### SUMMARY OF THE INVENTION

In one perspective of the present technology, nanoparticles having an initially relatively uniform size distribution are provided onto a surface for permanent or temporary formation into a subsequent article or component of manufacture. The particles are arranged by applied forces to form a desired distribution on the surface, especially a relatively uniform or evenly spaced distribution (e.g., with a standard deviation of number average relative proximity between particles of ±50%, 40%, 30%, 25%, 20%, 15%, 10%, and even 5% or less than each of these values The particles are usually electrically charged (e.g., triboelectrically, positive or negative, etc., before they are applied to a carrier surface, when they are applied or after applied, as by field charging of the particles after they have been non-uniformly deposited on a carrier surface) particles or magnetically susceptible particles, or any other field maneuverable particles which assists in their deposition and/or reorientation/redistribution upon the surface without permanent bonding of the particles to an initial position where the particles have been deposited on the surface. The particles may be temporarily deposited on the surface in a fairly random or completely random pattern by any available particle generation and particle transport system, such as mass application, such as dusting, spraying, non-imagewise toning, electrostatic toning, etc. The particles are then subjected to a uniform or pulsed or otherwise ordered field to redistribute the particles on the surface, which is why the particles are not initially permanently fixed at a position on the surface. The redistribution of the particles is done in a manner that distributes the particles in a more ordered arrangement and even in specifically ordered and designed patterns on the surface. The particles are then retained on the surface (e.g., fixed, as by heating, coating, bonding, chemical reaction or other physical or chemical means) or transferred (e.g., by a subsequent field driven transfer mechanism, pressure, or heat and pressure) to a permanent substrate or further intermediate transfer substrate. An Atomic Force Microscope (AFM), field array, electron beam, semi-conductor array, wide area array and other technologically available systems are among the means of creating or directing a field in a manner that can assist in particularly relocating the nanoparticles on or onto the initial temporary surface by applying an (e.g., the term “electrical” will be used to generically include any of the forces that can be used as elsewhere described herein) field that redistributes the particles according to the effects of the applied field from the source, such as, but not limited to an AFM. The field may be continuous or pulsed or non-uniformly periodic and the resolution of the application of the field and its effects corresponds closely with the field resolution of the AFM in the example of using an AFM, the electric field from the tip of the AFM may move a large number of nanoparticles concurrently in the scan direction of the AFM, thus creating relatively large periodic arrays of relatively uniformly spaced nanoparticles. By exercising planned and preferably computer driven control over the scan parameters (e.g., row and column dimensions, spacing between essentially pixel elements of deposition along the scan line, field intensity, etc.), the substrate can be intentionally patterned with the distribution of nanoparticle arrays.

Another aspect of technology originally described herein includes the provision of exposed surfaces of catalysts for nanotube deposition at the bottom of elongated pores and the used of the exposed catalyst surfaces to grow nanotubes within the pores to created ambient environment protected nanotube structures within the pores.

### BRIEF DESCRIPTION OF THE FIGURES

FIG. 1 shows a schematic of the concept of AFM and the optical lever: (left) a cantilever touching a sample; (right) the optical lever. Scale drawing; the tube scanner measures 24 mm in diameter, while the cantilever is 100 μm long.

FIG. 2 shows a schematic illustration of the meaning of “spring constant” as applied to cantilevers. Visualizing the cantilever as a coil spring, its spring constant k directly affects the downward force exerted on the sample.

FIG. 3 shows an electron micrograph of two 100 μm long V-shaped cantilevers (cantilevers from Park Scientific Instruments, Sunnyvale, Calif.).

FIGS. 4a, 4b and 4c show three common types of AFM tip. (a) normal tip (3 μm tall); (b) supertip; (c) Ultralever (also 3 μm tall).

FIG. 5 shows an exploded view of a tube scanner. Applying a voltage to one of the four outer quadrants causes that quadrant to expand and the scanner to tilt away from it (XY movement). A corresponding negative voltage applied to the opposite quadrant doubles the XY range while preventing vertical motion. Applying a voltage to the inner electrode causes the entire tube to expand or contract (Z movement).

FIG. 6 shows an AFM feedback loop. A compensation network (which in my AFM is a computer program) monitors the cantilever deflection and keeps it constant by adjusting the height of the sample (or cantilever).

FIG. 7 shows a comparison between atomic force microscopy and friction force microscopy.

FIG. 8 shows a 2.5×2.5 nm simultaneous topographic and friction image of highly oriented pyrolytic graphic (HOPG). The bumps represent the topographic atomic corrugation, while the coloring reflects the lateral forces on the tip. The scan direction was right to left.

FIG. 9 shows a perspective view of a substrate having areas of random particles, ordered particles and design-distributed particles resulting from the application or non-application of a field from a non-contact Atomic Force Microscope facing the side of the substrate carrying the nanoparticles.

FIG. 10 shows a schematic of transfer of a patterned set of nanoparticles from a first surface on which the particles were formed to a final or intermediate receptor surface.

FIG. 11 shows the growth of nanotubes on a surface having deposited ordered catalyst nanoparticles on the surface.

FIG. 12 shows embedded nanotubes grown from exposed catalyst inside a porous matrix at the bottom of pores.

### DETAILED DESCRIPTION OF THE INVENTION

A very general and generic description of the technology described herein comprises a method, system and apparatus for forming structures from nanoparticles comprising: providing a source of nanoparticles that are catalysts or seeds to growth of a second material; depositing the nanoparticles to a first support surface in a first distribution of the nanoparticles; applying a field to the nanoparticles on the first support surface that applies a force to the particles; rearranging the nanoparticles on the first support surface by the force from the field to form a second distribution of nanoparticles on the first support surface that is more ordered or more patterned than the first distribution of nanoparticles; and growing a nanostructure from the second distribution of nanoparticles using the nanoparticles as seeds or catalyst for the growth. The field, for example, may be any force field that can assist in the ordered redistribution of particles on the surface, such as especially an electrical field or a magnetic field. Before growing a structure, the second distribution of nanoparticles on the surface may be fixed to the first support surface for growing particles on the first surface or transferred to a second support surface and the growing occurs on the second support surface. The nanostructure may be made of an elemental material or a compound. The method may be practiced on a surface that preferably may be a flat surface having less than 1% of the flat surface with vertical features greater than a number average diameter for the nanoparticles being deposited. The method preferably may have an operational vacuum of less than 10⁻⁵ Torr is maintained over the surface continuously while nanoparticles are being deposited and until the structure is grown. The field may be applied to the deposited nanoparticles from a) a front side of the surface on which the particles are deposited without a field applicator contacting the front side of the surface, b) between the two substrates or c) from a back side of the surface on which the particles are deposited with a field applicator either contacting or not contacting the back side of the surface. The preferred nanostructure comprises a nanotube or circuitry structure. In addition to the field rearranging the particles, a biasing field opposed to the field rearranging the nanoparticles may be applied to provide control over influence of the field rearranging the nanoparticles.

One format for a system for forming structures from nanoparticles comprises: a source of nanoparticles that comprise catalysts or seeds for growth of a material; a surface for receiving a deposit of nanoparticles; a system for maintaining a vacuum over the surface while nanoparticles are being deposited in a first distribution of the nanoparticles; a field applicator that applies a field to the first distribution of nanoparticles on the surface, the field applicator applying a force to the particles within the vacuum system to form a second distribution of particles; a transfer system within the vacuum system for transferring the second distribution of particles to a material growth system and growing the material on the second distribution of nanoparticles using the second distribution of nanoparticles as seeds or catalysts for the growth. The operational environment may -provide for a vacuum of less than 10⁻⁵ Torr to be maintained over the surface, the transfer zone and the growth system continuously while nanoparticles are being deposited and until the structure is grown.

The present technology relates to a novel tool, system and process to create large quantity of patterned and ordered nanoparticles with excellent size control. Nanoparticles with preferably better than 10% or 5% size uniformity (e.g., less than ±5% standard deviation among number average particle distribution, such as measured by average particle diameters) can be provided by any available source, such as by being created using an ultra-high vacuum nonlithographic technique. A preferred method is based on atomic cluster formation from atoms or small clusters of atoms, such as those formed by vaporization or plasma techniques such as sputtered atoms. The particle or atom or molecule or cluster formation is then followed by mass filtering (or any other sizing technique) as needed, to provide the uniformity of nanoparticle sizes desired in the practice of the technology. The charged nanoparticles thus formed are then deposited onto a temporary or intermediate surface in a relatively random pattern. The random pattern of deposited particles (which are not permanenetly fixed to the temporary surface are then ordered and patterned using controlled field scanning. For electrically charged deposited nanoparticles, the use of an atomic force microscope (AFM) tip is one of the available ways of providing a field (an electrical field in this instance) that can pattern or order the particles. The electric field from the tip moves a large number of nanoparticles concurrently in the scan direction thus creating very large periodic arrays of uniformly spaced nanoparticles. Although not limited to this theory, it is believed that this method, as well as other field induced distribution methods operates by creating charges or fields in the particles that naturally repel similar charges or fields in adjacent particles (e.g., negative charges repel negative charges, N-magnetic poles repel N-magnetic poles). The combination of repelling forces assist in the even distribution of particles based on the even distribution of forces among the adjacent particles. Controlling the scan parameters controls the nanoparticle array charge and field properties. In one format of practicing this technology, an AFM tip scanning technique can be combined with application of additional voltages to the substrate to pattern the nanoparticle arrays. A major strength of this technique is its compatibility with silicon CMOS technology thus making it suitable for volume manufacturing. Also, the high quality ordered and patterned nanoparticles can be created on any substrate including silicon, ceramics, composites, glass and plastic (e.g., insulating or non-conductive surfaces of any type). As an alternative to AFM scanning, large array field application (e.g., a 2-dimensional large area array of field generators) can be practiced or a line array can be scanned across a surface (e.g., a one dimensional line of field generators can be swept across the surface with random particles).

One type of practice of the present technology relies upon a novel combination of apparatus used in a novel combination of steps, even though individual components of the apparatus and individual steps may separately known in other applications and uses. This one type of practice may include at least:
a) providing a source of relatively uniform nanoparticles (e.g., less than 20 nm, or less than 15 nm, or less than 10 nm or less than 5 nm particles with a standard size deviation of less than ±100%, ±50%, or ±25% or less as described elsewhere herein by number average of particles;
b) providing those particles with a capability of being moved by application of a field, especially an electromagnetic field (e.g., an electrical field or magnetic field), if the particles are not innately capable of being moved by a field (e.g., are magnetic rather than merely magnetically susceptible);
c) providing the field movable particles onto a substrate; and
d) rearranging the field movable particles on the substrate by applying a force or field to the particles on the surface to rearrange the particles on the surface.

The particles may be provided by any of the many variations of products and sources for nanoparticles, and may be filtered by mechanical, electrostatic means, or manufactured by any process that provides the particles in the size an distribution range desired for the process or selected for the specific ultimate use intended for the process or the resulting nanoparticle coated surface or final article. Any filtering technique that provides a useful size distribution of nanoparticles may also be used. The standard deviation indicated is designed for more precise applications and is not intended as a functional limitation on the general practice of the present technology. In some applications larger particles (generally requiring stronger field effects to move and locate the particles) may well be desirable, while in other cases, narrower size distributions and smaller size particles may be necessary. General range might be, for example, particles of from 2-15 nanometers (number average diameter), 3-18 nanometers (size average distribution), 2-20 nanometers (size or number average distribution), 2-10 nanometers, 2-5 nanometers, or 1-5 nanometers. The distribution may be considered along with percentage standard deviation limits or the standard percentage deviations may be considered separately, such as with standard deviations of the number average or size average particle sizes ±40%, ±30%, ±25%, ±20%, ±15%, ±12%, ±10%, ±8%, ±5%, or less.

The application of the force to rearrange particles usually is best applied without contact of the force applicator with the particles themselves or the side of the substrate carrying the particles (referred to herein as the “front side”). Thus, an electrical force can be applied from the front side by a non-contact Atomic Force Microscope or other precision stylus application system. Similarly a magnetic force can be applied by non-contact front side application of the field from a native magnetic stylus or pulsed electromagnetic stylus or tip. Typically, if the particles are charged (e.g., negative charge or positive charge), a like charge will be applied over the front side to assist in rearranging the particles. If an opposite charge were used from the front side, particles would tend to be lifted from the surface rather than be rearranged. If a stronger opposite field or charge is applied from the back side of the substrate or from within the substrate, an opposite charge (from that on the particles) may be applied from the front side without significant lifting of particles.

It is also possible to deposit nanotube growth catalyst particles onto a surface and distribute the catalyst particles in a similar manner to that disclosed herein for the deposition of the nanoparticles themselves, and then grow small nanotubes or nanoparticles on the surface of the deposited catalyst. Typical catalysts have been single metal, co-metal, or alloy metal particles such as derived from Co, Fe and Ni, although newer catalysts in clued those such as described in Published US Application 20070098622 which includes a carbide catalyst that contains at least elements (a transition metal element, In, C) or (a transition metal element, Sn, C), and in particular, it is preferable for the transition metal element to be Fe, Co or Ni. In addition to this carbide catalyst, a metal catalyst of (Fe, Al, Sn) and (Fe, Cr, Sn) are effective. From among these, catalysts such as Fe.sub.3InC_{0.5}, Fe₃InC_{0.5}Sn_{w} and Fe₃SnC are particularly preferable.

The force application may also be applied to the back side of the substrate with a controlled strength similar charge or opposite charge, and the force applicator may now contact the rear side of the support surface without concern for physical rearrangement of the nanoparticles by the force applicator. If a charge opposite that of the charge on the particles is used, no additional biasing charge would be required (although it might be used for better control and precision of field and particle distribution). If a same charge or field (magnetic field, North-South orientation of field) is used for the back side field application as the charge (or field) on the nanoparticles, a biasing force facing the front side of the support surface may be used to prevent particles from being repelled from the support surface. For example, the biasing front side field may be at least about 5% or 10% (or greater) stronger than the rear side field applied to the field susceptible particles. Stronger in this sense does not necessarily mean absolute strength at the point of emission or generation of the field, but rather the strength as it affects the movement of particles. For example, in relative non-unit terms, the biasing field may be 100 absolute units where generated and the backside field strength may be 120 absolute units. However, because of the proximity and medium through which the front side field is applied (e.g., a high vacuum, medium vacuum, low vacuum or other pressure, and the particular gaseous medium used (e.g., an inert gas, noble gas, non-reactive gas, etc.), the actual effective front side field strength may be 80 units, while the insulating or field shielding effect of the back side application may reduce the effective back side field strength from 120 units to 60 units, thus maintaining the particles on the support surface while the particles are being rearranged by the field(s) applied.

Where the particles are potentially reactive with various gases (e.g., oxygen, halogens, hydrogen, and the like) or other materials that may be in the particle application or particle rearranging environment, the particles should be protected against reaction, unless a reaction is desired (e.g., depositing aluminum nanoparticles in an oxidizing environment so that oxidized aluminum (e.g., alumina) nanoparticles are formed before, during or after deposition. The best method of protecting the particles is under vacuum conditions such as at about 10⁻¹⁰ Torr, or at least between about 10⁻⁵ Torr and 10⁻¹¹ Torr.

A presently preferred range of particle sizes (e.g., non-agglomerated particles average size or agglomerated particles average size) is between 1 and 20 nanometers, 1-15 nanometers, 2-20 nanometers, 2-15 nanometers, 2-10 nanometers, 5-15 nanometers and 5-10 nanometers, depending upon the particles process used, the particular article intended and the strength of the field(s) used.

The process of rearranging the particles is generally referred to as patterning of the particles, as the original deposition of particles tends to be random, if not completely random. Of note, when the particles are deposited on the surface, even though it is a relatively smooth surface (as with commercial grade silicon wafers), there is some topography on the support surface, such as rills, mounds, waves, modulations, random topographic events and the like. Particles when deposited on the surface may naturally seek to orient themselves along such topographic anomalies, and this is not considered a pattern or intended arrangement. Even with this incidental alignment of particles with the topography, after application of the field (by smooth field application, field array application, pulsed application, or the like), the particles tend to orient themselves in the applied field pattern and overcome the incidental tendency to align with topographic features. This can readily be seen with photomicroscopic views (e.g., scanning electron microscope images) of the randomly deposited particles and the patterned particles after application of the field.

Creation of ordered and patterned nanoparticles with high purity and good size control is a prerequisite for many device applications. The present technology opens the door for many commercial applications in biomedical, optical and electronic devices. Light emitting devices, sensors, single electron transistors and biomolecular tagging are only a small sample of potential applications.

The atomic force microscope (AFM) is a very high-resolution type of scanning probe microscope. The AFM was invented by Binnig, Quate and Gerber in 1985, and is one of the foremost tools for the manipulation of matter at the nanoscale.

The AFM consists of a cantilever (probe) with a sharp tip at its end that is used to scan the specimen surface. The probe is typically silicon or silicon nitride with a tip radius of curvature on the order of nanometers. When the tip is brought into close proximity of a sample surface, the Van der Waals force between the tip and the sample leads to a deflection of the cantilever according to Hooke's law. Typically, the deflection is measured using a laser spot reflected from the top of the cantilever into an array of photodiodes. However a laser detection system can be expensive and bulky; an alternative method in determining cantilever deflection is by using piezoresistive AFM probes. These probes are fabricated with piezoresistive elements that act as a strain gage. Using a Wheatstone bridge, strain in the AFM probe due to deflection can be measured, but this method is not as sensitive as laser deflection.

If the tip were scanned at a constant height, there would be a risk that the tip would collide with the surface, causing damage. Hence, in most cases a feedback mechanism is employed to adjust the tip-to-sample distance to maintain a constant force between the tip and the sample. Generally, the sample is mounted on a piezoelectric tube, that can move the sample in the z direction for maintaining a constant force, and the x and y directions for scanning the sample. The resulting map of s(x,y) represents the topography of the sample. However, with substrate surfraces that are ‘flat’ with respect to the possible variations in the up-and-down movement of the AFM tip, minimal to no feedback may be necessary.

Over the years additional modes of operation have been developed for the AFM. The primary modes of operation are contact mode, non-contact mode, and dynamic contact mode. In the contact mode operation, the force between the tip and the surface is kept constant during scanning by maintaining a constant deflection. In the non-contact mode, the cantilever is externally oscillated at or close to its resonance frequency. The oscillation is modified by the tip-sample interaction forces; these changes in oscillation with respect to the external reference oscillation provide information about the sample's characteristics. Because most samples develop a liquid meniscus layer, keeping the probe tip close enough to the sample for these inter-atomic forces to become detectable while preventing the tip from sticking to the surface presents a major hurdle for non-contact mode in ambient conditions. In dynamic contact mode, the cantilever is oscillated such that it comes in contact with the sample with each cycle, and then enough force is applied to detach the tip from the sample.

Schemes for non-contact and dynamic contact mode operation include frequency modulation and the more common amplitude modulation. In frequency modulation, changes in the oscillation frequency provide information about a sample's characteristics. In amplitude modulation (better known as intermittent contact, semi-contact, or tapping mode), changes in the oscillation amplitude yield topographic information about the sample. Additionally, changes in the phase of oscillation under tapping mode can be used to discriminate between different types of materials on the surface.

The AFM has several advantages over the scanning electron microscope (SEM). The AFM can produce images of materials as small as 1 nm, while the SEM is limited to around 100 nm. Unlike the electron microscope which provides a two-dimensional projection or a two-dimensional image of a sample, the AFM provides a true three-dimensional surface profile. Additionally, samples viewed by AFM do not require any special treatments (such as metal coatings) that would irreversibly change or damage the sample. While an electron microscope needs an expensive vacuum environment for proper operation, most AFM modes can work perfectly well in ambient air or even a liquid environment.

The AFM tends to image a maximum height on the order of micrometres and a maximum total scanning area of around 150 by 150 micrometres. At high resolution, the quality of an image is limited by the radius of curvature of the probe tip, and so the selection of appropriate dimensions on the tip for the required resolution is an important selection or design parameter in the operation of specific assembly processes, even though any commercial tip can be used for manufacture where less resolution or perfection of deposition is needed.

The atomic force microscope is one of about two dozen types of scanned-proximity probe microscopes. All of these microscopes work by measuring a local property—such as height, optical absorption, or magnetism—with a probe or “tip” placed very close to the sample. The small probe-sample separation (on the order of the instrument's resolution) makes it possible to take measurements over a small area. To acquire an image the microscope raster-scans the probe over the sample while measuring the local property in question. The resulting image resembles an image on a television screen in that both consist of many rows or lines of information placed one above the other. Unlike traditional microscopes, scanned-probe systems do not use lenses, so the size of the probe rather than diffraction effects generally limit their resolution.

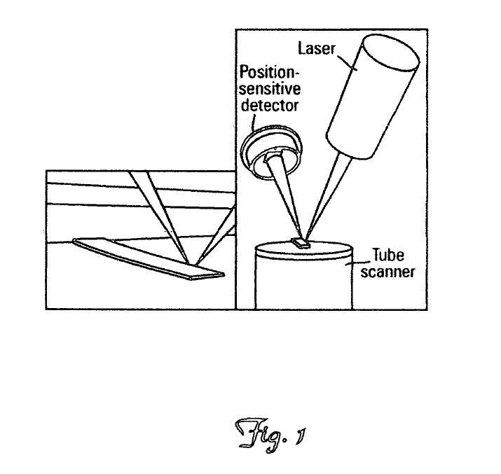

AFM (FIG. 1) operates by measuring attractive or repulsive forces between a tip and the sample. In its repulsive “contact” mode, the instrument lightly touches a tip at the end of a leaf spring or “cantilever” to the sample. As a raster-scan drags the tip over the sample, some sort of detection apparatus measures the vertical deflection of the cantilever, which indicates the local sample height. Thus, in contact mode the AFM measures hard-sphere repulsion forces between the tip and sample.

In non-contact mode, the AFM derives topographic images from measurements of attractive forces; the tip does not touch the sample. AFMs can achieve a resolution of 10 pm, and unlike electron microscopes, can image samples in air and under liquids. In principle, AFM resembles the record player as well as the stylus profilometer. However, AFM incorporates a number of refinements that enable it to achieve atomic-scale resolution:

Sensitive detection

Flexible cantilevers

Sharp tips

High-resolution tip-sample positioning

Force feedback

AFMs can generally measure the vertical deflection of the cantilever with picometer resolution. To achieve this, most AFMs use the optical lever, a device that achieves resolution comparable to an interferometer while remaining inexpensive and easy to use.

The optical lever (FIG. 1) operates by reflecting a laser beam off the cantilever. Angular deflection of the cantilever causes a twofold larger angular deflection of the laser beam. The reflected laser beam strikes a position-sensitive photodetector consisting of two side-by-side photodiodes. The difference between the two photodiode signals indicates the position of the laser spot on the detector and thus the angular deflection of the cantilever.

Because the cantilever-to-detector distance generally measures thousands of times the length of the cantilever, the optical lever greatly magnifies motions of the tip. Because of this ˜2000-fold magnification optical lever detection can theoretically obtain a noise level of about 10⁻¹⁴ m/Hz^{1/2}. For measuring cantilever deflection, to date only the relatively cumbersome techniques of interferometry and tunneling detection have approached this value.

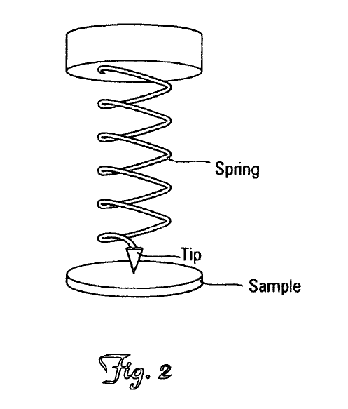

A high flexibility stylus exerts lower downward forces on the sample, resulting in less distortion and damage while scanning. For this reason AFM cantilevers generally have spring constants of about 0.1 N/m (FIG. 2).

It would take a very long time to image a surface by dragging the coiled cantilever system over the surface (in the configuration of FIG. 2), because the coiled system cannot respond quickly as it passes over features. That is, it has a low resonant frequency, but an AFM cantilever should have a high resonant frequency.

The equation for the resonant frequency of a spring:

$$resonant frequency = \frac{1}{2 π} \sqrt{\frac{spring constant}{mass}}$$

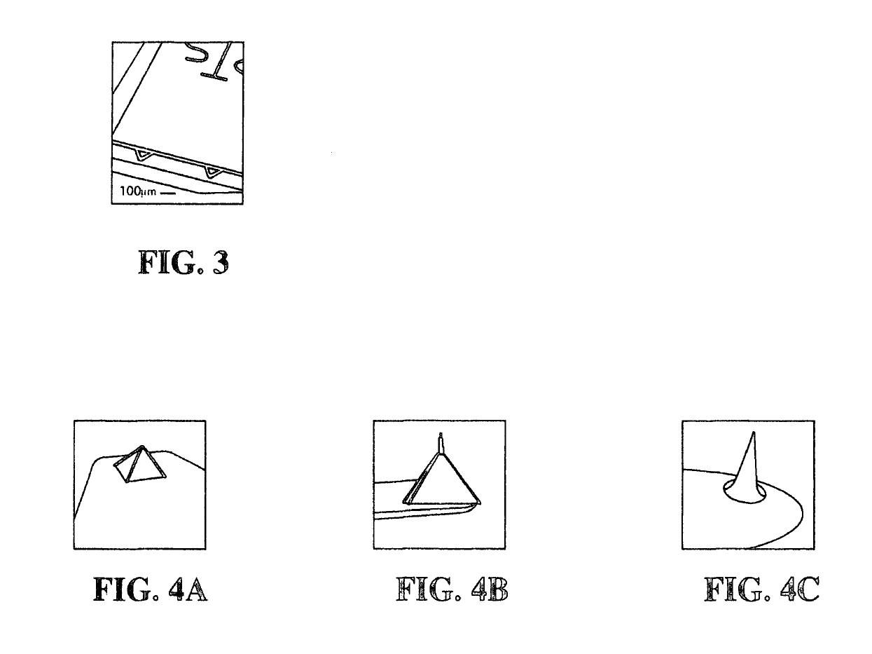

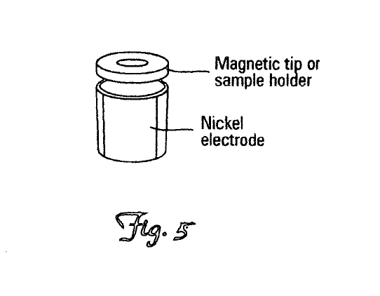

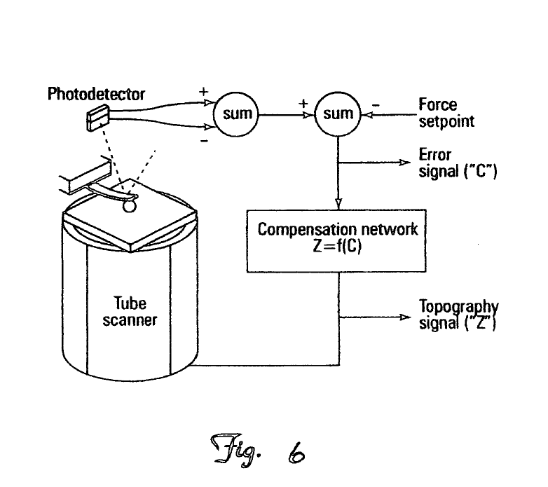

shows that a cantilever can have both low spring constant and high resonant frequency if it has a small mass. Therefore AFM cantilevers tend to be very small. Commercial vendors manufacture almost all AFM cantilevers by microlithography processes similar to those used to make computer chips. The cantilevers in FIGS. 3 and FIGS. 4a, 4b and 4c measure 100 μm in length and consist of silicon oxynitride with a thin coating of gold for reflectivity. Most users purchase AFM cantilevers with their attached tips from commercial vendors, who manufacture the tips with a variety of microlithographic techniques.

A close enough inspection of any AFM tip reveals that it is rounded off. Therefore force microscopists generally evaluate tips by determining their “end radius.” In combination with tip-sample interaction effects, this end radius generally limits the resolution of AFM. As such, the development of sharper tips is currently a major concern. Force microscopists generally use one of three types of tip. The “normal tip” (FIG. 4a) is a 3 μm tall pyramid with ˜30 nm end radius. The electron-beam-deposited (EBD) tip or “supertip” (FIG. 4b) improves on this with an electron-beam-induced deposit of carbonaceous material made by pointing a normal tip straight into the electron beam of a scanning electron microscope. Especially if the user first contaminates the cantilever with paraffin oil, a supertip will form upon stopping the raster of the electron beam at the apex of the tip for several minutes. The supertip offers a higher aspect ratio (it is long and thin, good for probing pits and crevices) and sometimes a better end radius than the normal tip. Finally, Park Scientific Instruments offers the “Ultralever” (FIG. 4c), based on an improved microlithography process. Ultralevers offers a moderately high aspect ratio and on occasion a ˜10 nm end radius.

Piezoelectric ceramics are a class of materials that expand or contract when in the presence of a voltage gradient or, conversely, create a voltage gradient when forced to expand or contract. Piezoceramics make it possible to create three-dimensional positioning devices of arbitrarily high precision. Most scanned-probe microscopes use tube-shaped piezoceramics because they combine a simple one-piece construction with high stability and large scan range. Four electrodes cover the outer surface of the tube, while a single electrode covers the inner surface. Application of voltages to one or more of the electrodes causes the tube to bend or stretch, moving the sample in three dimensions (FIG. 5).

AFMs use feedback to regulate the force on the sample as illustrated in FIG. 5. The presence of a feedback loop is one of the subtler differences between AFMs and older stylus-based instruments such as record players and stylus profilometers. The AFM not only measures the force on the sample but also regulates it, allowing acquisition of images at very low forces.

The feedback loop (FIG. 5) consists of the tube scanner that controls the height of the entire sample; the cantilever and optical lever, which measures the local height of the sample; and a feedback circuit that attempts to keep the cantilever deflection constant by adjusting the voltage applied to the scanner.

One point of interest: the faster the feedback loop can correct deviations of the cantilever deflection, the faster the AFM can acquire images; therefore, a well-constructed feedback loop is essential to microscope performance. AFM feedback loops tend to have a bandwidth of about 10 kHz, resulting in image acquisition times of about one minute. Almost all AFMs can measure sample topography in two ways: by recording the feedback output (“Z”) or the cantilever deflection (“error”; see FIG. 6). The sum of these two signals always yields the actual topography, but given a well-adjusted feedback loop, the error signal should be negligible. As described below, AFMs may have alternative imaging modes in addition to these standard modes.

Optical lever AFMs can measure the friction between tip and sample. If the scanner moves the sample perpendicular to the long axis of the cantilever (FIG. 6), friction between the tip and sample causes the cantilever to twist. A photodetector position-sensitive in two dimensions can distinguish the resulting left-and-right motion of the reflected laser beam from the up-and-down motion caused by topographic variations.

Therefore, AFMs can measure tip-sample friction while imaging sample topography. Besides serving as an indicator of sample properties, friction (or “lateral force,” or “lateral deflection”) measurements provide valuable information about the tip-sample interaction.

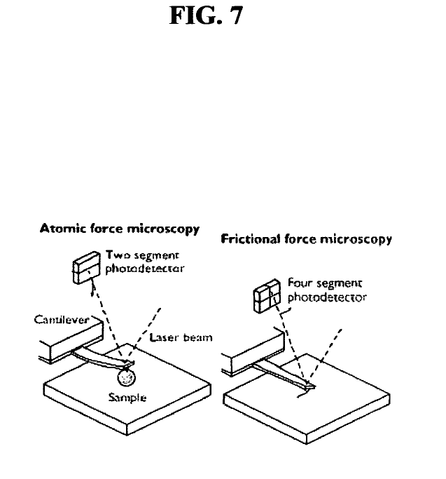

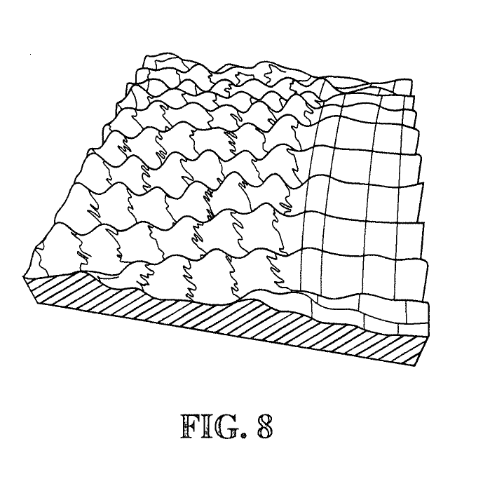

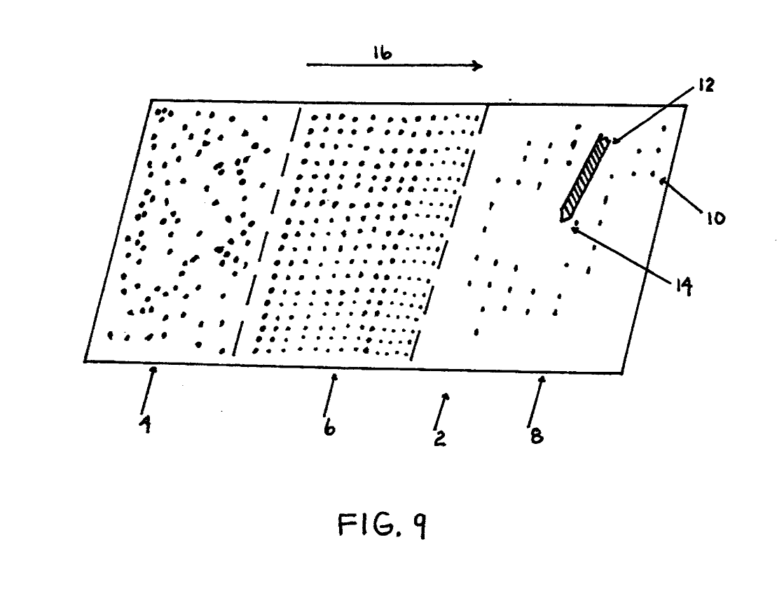

FIG. 7 shows a simultaneous friction and topography image of graphite atoms in which I have plotted the topography image as a three-dimensional projection colored by the friction data. Each bump represents one carbon atom. As the tip moves from right to left, it bumps into an atom and gets stuck behind it. The scanner continues to move and lateral force builds up until the tip slips past the atom and sticks behind the next one. AFM can also image the softness of a sample by pressing the cantilever into it at each point in a scan. The scanner raises the sample or lowers the cantilever by a preset amount, the “modulation amplitude” (usually 1-10 nm). In response, the cantilever deflects an amount dependent on the softness of the sample: the harder the sample, the more the cantilever deflects (FIG. 8).

When imaging in air, a layer of water condensation and other contamination covers both the tip and sample, forming a meniscus that pulls the two together. “Force curves” showing cantilever deflection as the scanner lowers the sample reveal the attractive meniscus force (FIG. 8): the cantilever has to exert an upward force to pull the tip free of the meniscus. This force equals the attractive force of the meniscus, usually 10-100 nN.

The great strength of the meniscus makes it the most important influence on the tip-sample interaction. Force microscopists often eliminate the meniscus by completely immersing both tip and sample in water.

FIG. 9 shows a substrate 2 with three different zones 4, 6 and 8 illustrated thereon. Each zone has nanoparticles 10 in different states of orientation. Zone 4 shows a representation of nanoparticles 10 in which the nanoparticles 10 have been randomly deposited. Zone 6 shows an area where the nanoparticles 10 have been repeatedly scanned by a field (e.g., an AFM) along scan direction 16 to provide an ordered array of nanoparticles 10. Zone 8 is a representation of an area where a particular and directed distribution of the field has been applied to position nanoparticles 10 in oriented positions to define specific distribution of nanoparticles 10. A field applicator 12 is shown, with a tip 14 that precisely directs the field close to the substrate 2.

The general technology described herein enables and describes both methods, apparatus and systems of forming structures from nanoparticles. A general method according to the present technology may comprise:

providing a source of nanoparticles (e.g., metal, metalloid, atomic, molecular, charged, magnetic, inorganic, organic, etc.), the particles being capable of being moved by application of a field, such as an electrical field, magnetic field and even electromagnetic radiation or fields such as light, UV, IR, radiowaves, radiation and the like;

depositing the nanoparticles to a surface in a first distribution of the nanoparticles;

applying a field to the nanoparticles on the surface that applies a force to the particles;

rearranging the nanoparticles on the surface by the force from the field to form a second distribution of nanoparticles on the surface. The second distribution of nanoparticles is more ordered or more patterned than the first distribution of nanoparticles as a result of the rearranging. The ordering phenomenon is not fully understood, but one explanation or hypothesis for the electrical field forces is that (for example with negatively charged particles applied to the nanoparticles deposited on the surface) the first application of particles is fairly randomly deposited because the charges on the individual particles do not significantly interact with each other and the particles tend to remain sufficiently far apart where the charge forces on the individual particles do not greatly interact, even when small clusters of particles associate on the surface, possibly because of responsive (positive) charge distributions crated on the surface. The application of locally strong or wide area strong field forces then strongly affects the relative position of the particles, possibly by destabilizing the same charged (negatively charged particles in a negative field) nanoparticles, allowing them to less strongly adhere to the surface, causing them to float more freely (as with a small wave lifting small articles from a sand beach), and allowing the interparticles charge effects to more easily order or rearrange the respective particles. The application of forces by an AFM cause those forces to be intense for short durations on a local scale, so that particle rearrangement patterns corresponding to the scan pattern on the surface can be viewed as result of the AFM scan. The field, as indicated above, may be an electromagnetic field, or may be an electrical field or a magnetic field. At present, a preferred field is an electrical field and electrically charged nanoparticles are deposited onto the surface. It is desirable that the surface is a flat surface. Flat is always a relative term, but in the practice of the present technology considerations of this term should be made with respect to a flat surface having less than 5%, less than 3%, less than 2% and preferably less than 1% of the total surface on which particles are deposited with vertical features greater than a number average diameter for the nanoparticles being deposited. For example, if 10 nm nanoparticles are deposited, less than 5% of the total surface area should have peaks or valleys that extend 10 nm or more above or below and average surface plane. As the particles get smaller, the topography variations should get smaller, although with 2 nm particles deposited, less than 5% of surface area with less than 5 nm features is satisfactory. The method, apparatus and system should maintain a vacuum of less than 10⁻⁵ Torr (e.g., 10⁻⁶ Torr is less than 10⁻⁵ Torr, even though it is a stronger vacuum) over the surface while nanoparticles are being deposited. In another alternative, the nanoparticles are magnetically susceptible and the field is a magnetic field. In a system and process control for the rearrangement, the field may be applied to the deposited nanoparticles from a front side of the surface on which the particles are deposited without a field applicator contacting the front side of the surface. Alternatively, field is applied to the deposited nanoparticles from a back side of the surface on which the particles are deposited with a field applicator either contacting or not contacting the back side of the surface. In addition to the field rearranging the particles, a biasing field opposed to the field rearranging the nanoparticles may be applied to provide control over influence of the field rearranging the nanoparticles, either with a same field orientation or an opposite field orientation as described above.

A system or apparatus for forming structures from nanoparticles may comprise:

a source of nanoparticles;

a surface for receiving a deposit of nanoparticles;

a system for maintaining a vacuum over the surface while nanoparticles are being deposited in a first distribution of the nanoparticles;

a field applicator that applies a field to the first distribution of nanoparticles on the surface, the field applicator applying a force to the particles within the vacuum system.

Computer or processor technology may preferably be integrated into the process, system and apparatus to provide greater automation to the system. The process may be operated in a batch mode or continuous mode, with the substrate moving continuously through the particle source zone, particle application zone, and particle rearrangement zone under a continuous vacuum.

After development of the distribution of the particles on the substrate, the particles, when catalysts or seed materials for the deposition of linear growth materials or even surface growth materials, can be used in any deposition process that deposits growth materials onto the catalyst or seed surface. The use of these patterned and/or ordered particles have significant advantages, such as the fact that the nanotubes and nanofiber arrays created by this technique have almost zero excess catalyst material. In addition, all nanotubes and nanofibers are physically separated and electrically isolated from each other. The underlying principle for this technique is the use of a single nanoparticle for the growth of a single nanotube or nanofiber; and the array of nanotubes and nanofibers is obtained by using an array of catalyst nanoparticles that are physically separated from each other. In addition, a major strength of this technique is that periodic and ordered arrays of nanotubes and nanofibers can also be created by ordering the catalyst nanoparticles ahead of the growth, using an ordering technique such as electric field induced ordering by an AFM tip. While this technique has been primarily developed for carbon nanotubes and nanofibers, it can also be equally applied for the creation of nanotube and nanofiber arrays of other materials.

The particular nanotubes used in conjunction with the processes described herein are not particularly limited by their method of deposition promoted by the catalysts or enhanced by the seeds, insofar as the nanotubes themselves do not detract from the features of the present invention. For example, commercially available products, methods and apparatus for the deposition of materials for growth of nanotubes may be used in combination with the particle deposition methods, apparatus and compositions described herein. Also, the nanotubes are not limited by their production process such as arc discharge, laser ablation, hot-filament plasma chemical vapor deposition, microwave plasma chemical vapor deposition, thermochemical vapor deposition, pyrosis processes, etc. Any process that can provide depositable material in any way to the nanotube growth system can be used in combination with the underlying patterned or ordered deposition of particles used in assisting growth of the nanotubes. Such methods might, by way of non-limiting examples, include methods disclosed in U.S. Pat. No. 7,011,771 (Gao); U.S. Pat. No. 6,998,103 (Phillips); U.S. Pat. No. 6,949,237 (Smalley); U.S. Pat. No. 7,032,437 (Lee); U.S. Pat. No. 6,855,376 (Hwang); U.S. Pat. No. 6,455,021 (Saito); and the like.

The nanotubes grown on the deposited particles as described herein are relatively robust because of their actual growth on the surface of the carrier or substrate. Therefore, after the nanotubes have been formed, it is also possible to perform any further desired or required processes to them. Since the carbon nanotubes fabricated by any one of these processes include impurities, for example, carbon-containing materials such as amorphous carbons, fullerenes, graphite, etc., and transition metals such as nickel (Ni), iron (Fe), etc., used as catalysts for carbon nanotube growth, additional processes are required to remove the impurities. For example, after the carbon nanotubes are refluxed in an HNO₃ aqueous solution (2 to 3M) for about 48 hours, the resulting mixture is centrifuged at about 2000 rpm for about 30 minutes to separate precipitates and a supernatant of acid solution. The supernatant is removed, and the precipitates are dispersed in distilled water, centrifuged, and separated from a supernatant. These series of processes are repeated three or more times. Then the finally obtained precipitates are dispersed in an aqueous solution containing a surfactant and the dispersion is adjusted to a pH of 10 or higher using sodium hydroxide (NaOH). After the resulting mixture is subjected to a sonication process for about 10 hours, an excess of hydrochloric acid (HCl) is added to precipitate single wall carbon nanotubes (SWNT). Subsequently, the solution is centrifuged to remove an aqueous acid solution from the precipitated slurry. The slurry is passed through a membrane filter with a pore size of 1 millimicron to obtain purified single wall carbon nanotubes. In addition to the process discussed above, the carbon nanotubes can be purified by any known process.

The fundamental process of the described technology therefore includes forming a patterned array of particles on a substrate, preferably by the proprietary technology of the present disclosure, and then subsequently growing nanotubes by any available process from the catalysts/seeds on the substrate. The catalyst or seed must be appropriate for the nanotube to be grown, such as metals, inorganics, nitrides and the like for carbon or graphitic nanotubes. The materials grown as nanotubes may be based on atomic deposition, molecular deposition, deimeric, trimeric or polymeric deposition, and may, by way of non-limiting examples include atomic materials (atoms or elements), simple compounds, complex compounds and the like which are organic, inorganic or mixed organic or inorganic materials, such as carbon, boron, metals, semimetals, silicon, boron nitride, silica, alumina, ethylenically unsaturated monomers or polymers, amidic monomers or polymers, and the like. Where appropriate, magnetic, electromagnetic and voltaic fields may be applied to assist in the rate, shape or properties of the growing nanotubes.

Once the particles have been formed on a first substrate, which may require properties particularly for the deposition and may therefore be a substrate that is undesirable for the ultimate growth of the naontubes, because of any reason such as cost, shape, substrate material properties, substrate material appearance and the like. The particles formed on the substrate, if they have not been fixed to the surface (e.g., by activation of a polymerizable coating of material on the surface of the substrate, fusion, heat, pressure or combinations thereof) are formed in a pattern sustained by local destructible forces and may be transferred from the surface to a final substrate surface by any of field control (e.g., magnetic or electrical field application with non-contact transfer of the particles or contact transfer of the particles from the forming substrate to the final substrate.

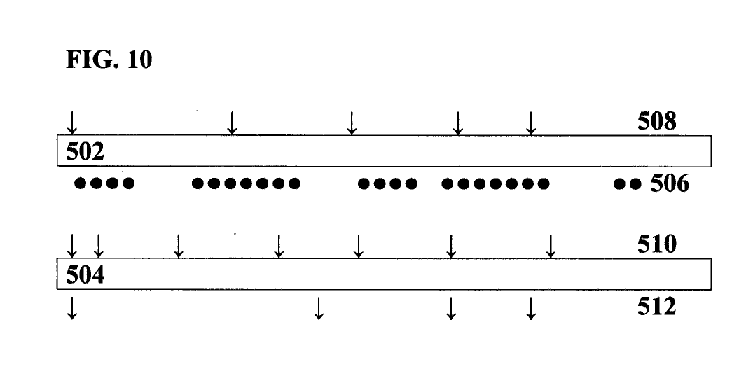

FIG. 10 shows a schematic of transfer of a patterned set of nanoparticles 506 from a first substrate 502 on which the particles 506 were formed to a final or intermediate receptor substrate 504. A field may be applied in various ways when the field is capable of moving, controlling, directing or otherwise repositioning or forcing the particles 506 so that they transfer from the original substrate 502 on which they were deposited to a second sustrate 504 on which the particles are desired to be present in their original pattern or in a modified or different pattern (based upon the control of field and current). For example, the spacing between the two substrates 502 and 504 is selected to be appropriate for the particles used, the fields used, the resolution required, the substrate materials, and the like. A first field 508 may be used from the backside of the substrate 502 to drive the nanoparticles 506 away from the first substrate 502 towards the second substrate 504. For example, if the particles 506 have a negative electrical charge, the application of negative electrical fields or charges as field 508 will motivate particles 506 away from the first substrate 502 towards the second substrate 504. The field or charges 508 may be created or applied on a point-by-point (e.g., stylus or head) basis, a line basis (moving a wire or edge that covers a length across a section of the backside), or a field basis (e.g., having a wide area array of electrodes or generators. Magnetic fields may be applied from the backside of the first substrate 502 as the sole driving force only if there is an opposite polarity between the particles 506 and the magnetic field, or is the magnetic field 508 is applied as a control or biasing field in combination with a stronger dring field, such as field 512 on the opposite side of the second substrate 504. That field 512 would draw a magnetically susceptible particle or different polarity magnetic particle from the first substrate 502 to the second substrate 504 and might be controlled, enhanced or balanced partially by the first field 508. A field 510 may be applied across the area between the two substrates 502 and 504 to move particles from one surface to another. Contact pressure and heat in combination with these fields may be used to move or fix the particles. For example, if the original substrate were silicon wafers (silica) and the second substrate was a polymeric material (particularly a heat softenable polymeric material), heat and/or pressure could be used to fix the nanoparticles to the second substrate 504 without fixing particles to the first substrate.

Once the distribution of particles has been formed, the nanotubes can be grown from the distribution of catalysts or the particles transferred to a more desirable surface, such as a conductive surface (e.g., metallic, metal coated, metalloid, metal-filled, carbon filled, etc.).

As the particles (either on the original substrate or the substrate to which they have been transferred) act as seeds or catalysts, and in some technologies as directional seeds or catalysts (e.g., the growth of the nanotube would be in a single direction perpendicular to the approximate plane of the substrate and the surface of the particle on that surface), the nanotubes grow in a perpendicular line from the surface and grow in parallel lines to other nanotubes.

FIG. 11 shows a schematic perspective view of a surface 600 having two deposited rows of catalyst particles 602 from which have been grown nantubes 604. As can be seen, the nanotubes 604 are exposed to the environment.

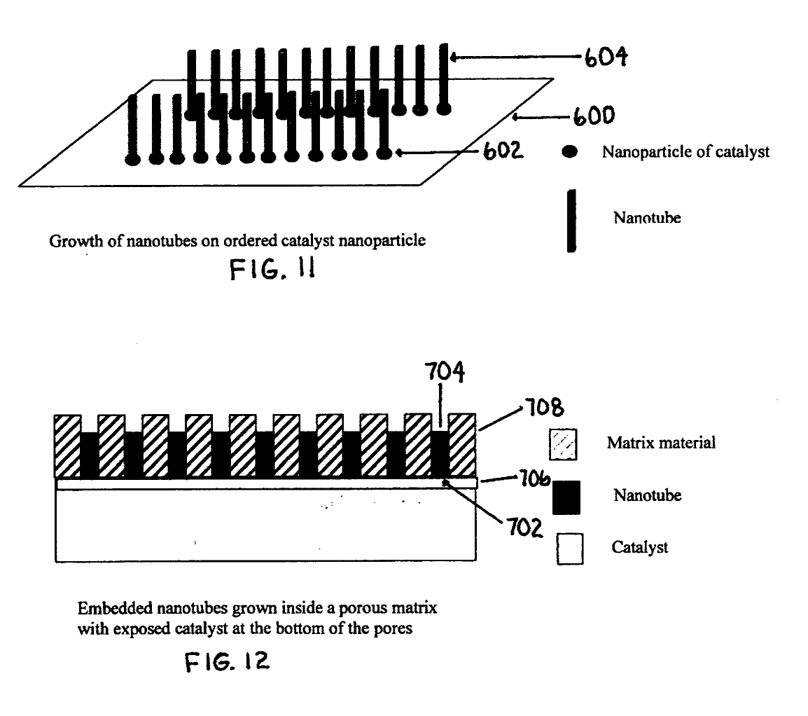

FIG. 12 shows embedded nanotubes 704 grown from exposed catalyst 702 resulting from a continuous substrate of catalyst 706. The continuous layer of catalyst 706 may have had the exposed areas 702 formed by etching through the covering matrix material 708, which may itself have been a continuous layer before etching (e.g., anodization by well known anodization techniques known in the metal fabrication, metal treatment, and printing industries. These techniques can produce regularly spaced, uniform dimensioned, uniform depth pores in the matrix, such as aluminum or other anodizable metals. Alternatively, the porous matrix may be formed and laminated to the surface of the continuous catalyst layer. A laminable matrix may be formed of polymeric materials, as by embedding nanosize (diameter) filaments of soluble material inside a solvent resistant polymer and then dissolving the soluble fibers out of the matrix, leaving the pores. It is also possible to use positive-acting lithographic compositions that can be exposed to create soluble pores that are removed from the matrix, which is then laminated. Such systems and compositions are also well known in the printing industry and photolithographic industry, Such compositions are disclosed in U.S. Pat. Nos. 5,981,135; 5,901,618; 5,665,522; 5,650,261; 5,542,273; 5,498,506; 5,384,238; 4,910,186; 4,889,787; 4,829,046; 4,824,757; 4,806,453; 4,690,882; and 4,672,020, which are incorporated herein by reference. By providing the through-holes in the matrix, areas of the catalyst layer are exposed at the bottom of the pores. As nanotube structure can be built linearly on the exposed catalyst, the nanotube is formed inside a porous matrix at the bottom of pores.

These nanotube structures formed within linear pores in the matrix enable functional structure (e.g., dimensionality, orientation, spacing, directionality) to be built into the structure. This can have particular benefits with respect to field emission systems, electron emission systems, projection systems, conductive systems and the like. Additionally, as the forming process can be performed in a vacuum environment, the entire finished system may also be sealed by application of a layer over the pores, preventing access to the nanotubes by oxidizing environments and materials, corrosive environments and materials, and the like. Polymeric overcoating of the pores is most preferred to effect this result.

The technology also therefore includes disclosure of a method of forming nanotube structures comprising providing a first layer having an array of pores through the first layer, providing at the bottom of at least some pores a catalyst for the deposition growth of nanotubes, providing a deposition environment for the deposition of nanotube material into the pores, and growing nanotubes within the pores. The method may have the first layer comprise a metallic layer that has been anodized to form the pores. The metallic layer may be first placed over a second layer comprising the catalyst and the first layer is anodized to produce pores passing from a top of the first layer through a bottom of the first layer to expose catalyst. The first layer may be formed with pores thereon and then laminated to the layer of catalyst prior to growing nanotubes within the pores.

A cover layer (e.g., polymer or ceramic or composite) may be placed over the pores with nanotubes therein and a vacuum/void area between the top of the nanontube and the cover layer. The vaccum may have been present during the manufacture of the nanotubes or applied after nanotube growth and before application of the cover layer. Alternatively an inert gas may be present in the gap between nanotube and cover layer to prevent oxidation of the extremely thin (and therefore fragile) nanotube material.

Other options, variations, alternatives and controls over the system will be apparent to those skilled in the art upon reading this technical disclosure.

What is claimed:

1. A method of forming structures from nanoparticles comprising:
providing a source of nanoparticles that are catalysts or seeds to growth of a second material;
depositing the nanoparticles to a surface in a first distribution of the nanoparticles;
applying a field to the nanoparticles on the surface that applies a force to the particles;
rearranging the nanoparticles on the surface by the force from the field to form a second distribution of nanoparticles on the surface that is more ordered or more patterned than the first distribution of nanoparticles; and
growing a structure from the second distribution of nanoparticles using the nanoparticles as seeds or catalyst for the growth.

2. The method of claim 1 wherein the field is an electrical field or a magnetic field.

3. The method of claim 1 wherein before growing a structure, the second distribution of nanoparticles on the surface is transferred to a second surface and the growing occurs on the second surface

4. The method of claims 1 wherein the structure is made of an elemental material or a compound, .

5. The method of claim 1 wherein the surface is a flat surface having less than 1% of the flat surface with vertical features greater than a number average diameter for the nanoparticles being deposited.

6. The method of claim 1 wherein a vacuum of less than 10⁻⁵ Torr is maintained over the surface continuously while nanoparticles are being deposited and until the structure is grown.

7. The method of claim 3 wherein a vacuum of less than 10⁻⁵ Torr is maintained over the surface continuously while nanoparticles are being deposited and until the structure is grown.

8. The method of claim 1 wherein the field is applied to the deposited nanoparticles from a) a front side of the surface on which the particles are deposited without a field applicator contacting the front side of the surface or b) from a back side of the surface on which the particles are deposited with a field applicator either contacting or not contacting the back side of the surface.

9. The method of claim 1 wherein the structure comprises a nanotube.

10. The method of claim 1 wherein in addition to the field rearranging the particles, a biasing field opposed to the field rearranging the nanoparticles is applied to provide control over influence of the field rearranging the nanoparticles.

11. The method of claim 3 wherein the structure comprises a nanotube.

12. The method of claim 7 wherein the structure comprises a nanotube.

13. The method of claim 8 wherein the structure comprises a nanotube.

14. The method of claim 10 wherein the structure comprises a nanotube.

15. A system for forming structures from nanoparticles comprising:
a source of nanoparticles that comprise catalysts or seeds for growth of a material;
a surface for receiving a deposit of nanoparticles;
a system for maintaining a vacuum over the surface while nanoparticles are being deposited in a first distribution of the nanoparticles;
a field applicator that applies a field to the first distribution of nanoparticles on the surface, the field applicator applying a force to the particles within the vacuum system to form a second sitribution of particles;
a transfer system within the vacuum system for transferring the second distribution of particles to a material growth system and growing the material on the second distribution of nanoparticles using the second distribution of nanoparticles as seeds or catalysts for the growth.

16. The system of claim 15 wherein a vacuum of less than 10⁻⁵ Torr is maintained over the surface, the transfer zone and the growth system continuously while nanoparticles are being deposited and until the structure is grown.

17. A method of forming nanotube structures comprising providing a first layer having an array of pores through the first layer, providing at the bottom of at least some pores a catalyst for the deposition growth of nanotubes, providing a deposition environment for the deposition of nanotube material into the pores, and growing nanotubes within the pores.

18. The method of claim 17 wherein the first layer comprises a metallic layer that has been anodized to form the pores.

19. The method of claim 18 wherein a metallic layer is first placed over a second layer comprising the catalyst and the first layer is anodized to produce pores passing from a top of the first layer through a bottom of the first layer to expose catalyst.

20. The method of claim 19 wherein the first layer is formed with pores thereon and then laminated to the layer of catalyst prior to growing nanotubes within the pores.
